(19) United States
(12) Patent Application Publication
(10) Pub. No.: US 2005/0072983 A1
(43) Pub. Date: Apr. 7, 2005

(54) Method for manufacturing light emitting diode utilizing metal substrate and metal bonding technology and structure thereof

(75) Inventors: Pan-Tzu Chang, Hsinchu County (TW); Ying-Che Sung, Taoyuan County (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Arima Optoelectronics Corp., Taoyuan County (TW)

(21) Appl. No.: 10/870,186

(22) Filed: Jun. 17, 2004

(30) Foreign Application Priority Data
Oct. 7, 2003 (TW) 092127877

(51) Int. Cl. H01L 29/06

(52) U.S. Cl. 257/94

(57) ABSTRACT

A method for manufacturing the light emitting diode utilizing the metal substrate and the metal bonding technology is provided. The method includes steps of providing a growing substrate, forming a multi-layered semiconductor structure on the growing substrate, bonding a metal substrate to the multi-layered semiconductor structure, removing the growing substrate, and forming a first electrode and a second electrode on the multi-layered semiconductor structure and the metal substrate respectively.

### FIELD OF THE INVENTION

This invention relates to a method for manufacturing a light emitting diode and a structure thereof, and more particularly to a method for manufacturing a light emitting diode utilizing a metal substrate and a metal bonding technology and a structure thereof.

### BACKGROUND OF THE INVENTION

The light emitting diode (LED) is a luminescent light emitting component, which emits light through exerting current to the material of compound semiconductors of III-V groups and then utilizing the radiative recombination of electrons and holes inside the diode so as to transform the energy into the form of light. It will not get burned like the incandescent lamp will when being used for a long time. In addition, the light emitting diode further has the advantages of small volume, long lifespan, low driving voltage, rapid response rate and good vibration-resisting property, so that it has become a very popular product in daily life.

There are many kinds of light emitting diodes. Through utilizing different materials of compound semiconductors and the element structures, the light emitting diodes with different colors such as red, orange, yellow, green, blue and purple as well as the invisible light like ultrared and ultraviolet ones have been designed to be widely used in outdoor signboards, brake lamps, traffic signs, displays and so on.

Take AlGaInP light emitting diode as an example, AlGaInP is a four-element compound semiconductor material and suitable for manufacturing red, orange, yellow and yellow-green light emitting diodes with high brightness. The AlGaInP light emitting diode has a high light-radiating efficiency and the lattices thereof are grown and matched on a GaAs substrate. However, because GaAs substrate is a light-absorbing substrate, it will absorb the visible light emitted from AlGaInP. Besides, GaAs substrate has a poor heat conductivity. Therefore, the light-radiating efficiency is limited when LEDs are driven at high current level.

From above description, it is known that how to develop a new method for manufacturing a light emitting diode and a structure thereof with the advantage of better heat-dissipating efficiency has become a major problem to be solved. In order to overcome the drawbacks in the prior art, a method for manufacturing a light emitting diode and a structure thereof are provided. The particular design in the present invention not only solves the problem described above, but also enhances the light-radiating efficiency. Moreover, the procedures of the method in the present invention are simple and easy to perform.

### SUMMARY OF THE INVENTION

It is an object of the present invention to provide a method for manufacturing the light emitting diode that utilizes the metal bonding technology to bond a metal substrate so as to replace the original GaAs substrate for crystal growth.

It is another object of the present invention to provide a method for manufacturing the light emitting diode so as to significantly reduce the required temperature in the bonding process.

It is further object of the present invention to provide a method for manufacturing the light emitting diode so as to effectively diminish the production cost and enhance the yield.

It is further another object of the present invention to provide a method for manufacturing the light emitting diode which possesses great heat-dissipating capability so that the light-radiating efficiency thereof can be significantly enhanced.

In accordance with one aspect of the present invention, a method for manufacturing a light emitting diode includes steps of providing a growing substrate, forming a multi-layered semiconductor structure on the growing substrate, bonding a metal substrate to the multi-layered semiconductor structure, removing the growing substrate, and forming a first electrode and a second electrode on the multi-layered semiconductor structure and the metal substrate respectively.

Preferably, the growing substrate is a GaAs substrate.

Preferably, the multi-layered semiconductor structure is a light emitting diode.

Preferably, the light emitting diode is formed by a four-element material of AlGaInP.

Preferably, the metal substrate is bonded to the multi-layered semiconductor structure by means of a metal bonding technology.

Preferably, the metal bonding technology is performed through plating a metal bonding layer on the multi-layered semiconductor structure and then bonding the metal substrate to the multi-layered semiconductor structure via the metal bonding layer.

Preferably, the metal bonding layer is one selected from a group consisting of an AuBe, an AuSn, an AuGe, an AuNi, an AuZn, an Au, an AuSi, an Al, an AlSi, an InAu, an InAg, and Ag thin films.

Preferably, the metal bonding technology is performed at a bonding temperature ranged from 300° C. to 900° C.

Preferably, the metal bonding technology is performed at a bonding pressure ranged from 500 pounds to 5000 pounds.

Preferably, the first electrode and the second electrode are respectively a P-type electrode and an N-type electrode.

Preferably, the first electrode and the second electrode are respectively an N-type electrode and a P-type electrode.

Preferably, the metal substrate is made of a material selected from a group consisting of a Mo, a MoCu alloy, a W, a WCu alloy, a Cr and a CrCu alloy.

In accordance with another aspect of the present invention, a light emitting diode structure includes a multi-layered semiconductor structure for emitting light, a metal substrate formed on the multi-layered semiconductor structure by means of a bonding technology, and a first electrode and a second electrode respectively formed on the multi-layered semiconductor structure and the metal substrate for providing a current to the multi-layered semiconductor structure.

Preferably, the multi-layered semiconductor structure is a light emitting diode.

Preferably, the light emitting diode is formed by a four-element material of AlGaInP.

Preferably, the metal substrate is bonded to the multi-layered semiconductor structure by means of a metal bonding technology.

Preferably, the metal bonding technology is performed through plating a metal bonding layer on the multi-layered semiconductor structure and then bonding the metal substrate to the multi-layered semiconductor structure via the metal bonding layer.

Preferably, the metal bonding layer is one selected from a group consisting of an AuBe, an AuSn, an AuGe, an AuNi, an AuZn thin, an Au, an AuSi, an Al, an AlSi, an InAu, an InAg, and Ag films.

Preferably, the metal bonding technology is performed at a bonding temperature ranged from 300° C. to 900° C.

Preferably, the metal bonding technology is performed at a bonding temperature ranged from 500 pounds to 5000 pounds.

Preferably, the first electrode and the second electrode are respectively a P-type electrode and an N-type electrode.

Preferably, the first electrode and the second electrode are respectively an N-type electrode and a P-type electrode.

Preferably, the metal substrate is made of a material selected from a group consisting of a Mo, a MoCu alloy, a W, a WCu alloy, a Cr and a CrCu alloy.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1(a)˜1(d) are schematic diagrams showing a manufacturing method of a light emitting diode according to a preferred embodiment of the present invention.

### DETAILED DESCRIPTION OF THE PREFERRED EMBODIMENT

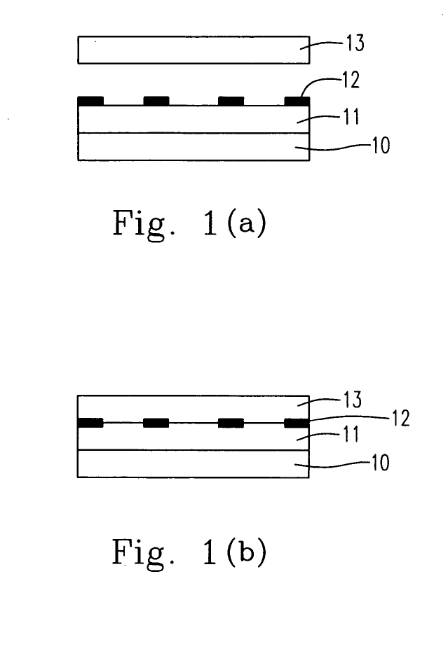

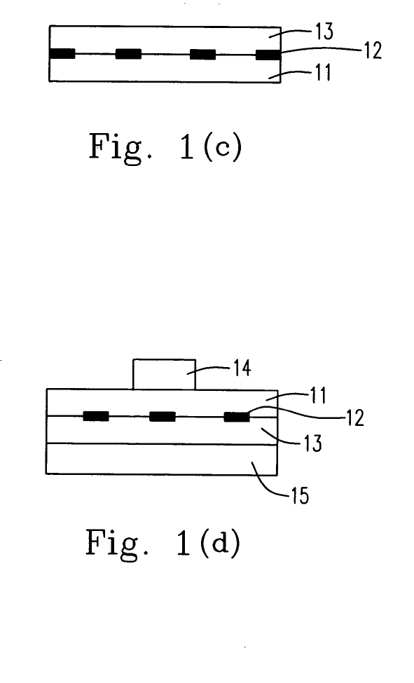

The present invention will now be described more specifically with reference to the following embodiments. Please refer to FIGS. 1(a)˜1(d), which shows a manufacturing method of a light emitting diode according to a preferred embodiment of the present invention. The procedures of the method are as follows.

At first, a growing substrate 10, such as a GaAs substrate, is provided. Next, a multi-layered semiconductor structure 11 is formed on the growing substrate 10 through proceeding the crystal growth. The multi-layered semiconductor structure 11 is a light emitting diode structure composed of multiple layers of different material with different thickness, such as GaAs, GaAsP, AlGaAs and AlGaInP. In which, AlGaInP is preferred. Because the crystal growth technology belongs to the prior art, it is not repeatedly described here.

For improving the problem of the poor heat conductivity of the GaAs substrate, a metal bonding technology is employed in the present invention for bonding a metal substrate 13 so as to replace the original GaAs substrate. By means of the metal bonding technology, the metal bonding layer 12 is plated on the multi-layered semiconductor structure 11 after the process of crystal growth. The metal bonding layer 12 is one selected from a group consisting of an AuBe, an AuSn, an AuGe, an AuNi, an AuZn, an Au, an AuSi, an Al, an AlSi, an InAu, an InAg, and In thin films. With conditions that the temperature is controlled within a range from 300° C. to 900° C. (the range from 400° C. to 700° C. is preferred) and the pressure is controlled within a range from 500 pounds to 5000 pounds (the range from 1500 pounds to 3500 pounds is preferred), the metal substrate 13 is bonded with and ohmically contacted with the multi-layered semiconductor structure 11 via the metal bonding layer 12, as shown in FIG. 1(b). In which, the metal substrate 13 is made of a material selected from a group consisting of a Mo, a MoCu alloy, a W, a WCu alloy, a Cr and a CrCu alloy. And the bonded structure is shown in FIG. 1(b).

Then, the growing substrate 10 is removed from the bonded structure by the way of polish and chemical etching, as shown in FIG. 1(c). Afterward, the P-type electrode 15 and the N-type electrode 14 are respectively formed on the metal substrate 13 and the multi-layered semiconductor structure 11 for providing a current to the multi-layered semiconductor structure 11 so as to make the multi-layered semiconductor structure 11 to emit light in response to the current, as shown in FIG. 1(d).

In view of the aforesaid discussion, the present invention utilizes the metal bonding technology to bond a metal substrate so as to replace the original GaAs substrate for crystal growth. Because the heat-dissipating ability of the metal substrate is several times higher than that of the GaAs substrate, when the light emitting diode is driven at high current level and operated at a range from several hundred milliamperes to several amperes, the output power thereof will not influence the light-radiating efficiency on account of the poor heat dissipation of the substrate. Compared with the traditional wafer bonding technology utilizing the semiconductor as a bonding layer that has to be bonded at a high temperature larger than 900° C., the metal bonding temperature of the present invention is ranged from 300° C. to 900° C. so that the required temperature in the bonding process can be significantly reduced. Furthermore, the production cost can be effectively reduced and the yield can be enhanced.

Since the light emitting diode of the present invention possesses great heat-dissipating characteristics plus the mirror reflection of the metal bonding layer, the light-radiating efficiency thereof can be significantly enhanced. In the application of high brightness, high power and large superficial measure in the future, the light emitting diode with the use of metal substrate and metal bonding technology provided in the present invention will have great market potential.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for manufacturing a light emitting diode, comprising steps of:
providing a growing substrate;
forming a multi-layered semiconductor structure on said growing substrate;
bonding a metal substrate to said multi-layered semiconductor structure;
removing said growing substrate; and
forming a first electrode and a second electrode on said multi-layered semiconductor structure and said metal substrate respectively.

2. The method as claimed in claim 1, wherein said growing substrate is a GaAs substrate.

3. The method as claimed in claim 1, wherein said multi-layered semiconductor structure is a light emitting diode.

4. The method as claimed in claim 3, wherein said light emitting diode is formed by a four-element material of AlGaInP.

5. The method as claimed in claim 1, wherein said metal substrate is bonded to said multi-layered semiconductor structure by means of a metal bonding technology.

6. The method as claimed in claim 5, wherein said metal bonding technology is performed through plating a metal bonding layer on said multi-layered semiconductor structure and then bonding said metal substrate to said multi-layered semiconductor structure via said metal bonding layer.

7. The method as claimed in claim 6, wherein said metal bonding layer is one selected from a group consisting of an AuBe, an AuSn, an AuGe, an AuNi and an AuZn thin films.

8. The method as claimed in claim 5, wherein said metal bonding technology is performed at a bonding temperature ranged from 300° C. to 900° C.

9. The method as claimed in claim 5, wherein said metal bonding technology is performed at a bonding pressure ranged from 500 pounds to 5000 pounds.

10. The method as claimed in claim 1, wherein said first electrode and said second electrode are respectively a P-type electrode and an N-type electrode.

11. The method as claimed in claim 1, wherein said first electrode and said second electrode are respectively an N-type electrode and a P-type electrode.

12. The method as claimed in claim 1, wherein said metal substrate is made of a material selected from a group consisting of a Mo, a MoCu alloy, a W, a WCu alloy, a Cr and a CrCu alloy.

13. A light emitting diode structure, comprising:
a multi-layered semiconductor structure for emitting light;
a metal substrate formed on said multi-layered semiconductor structure by means of a bonding technology; and
a first electrode and a second electrode respectively formed on said multi-layered semiconductor structure and said metal substrate for providing a current to said multi-layered semiconductor structure.

14. The light emitting diode structure as claimed in claim 13, wherein said multi-layered semiconductor structure is a light emitting diode.

15. The light emitting diode structure as claimed in claim 14, wherein said light emitting diode is formed by a four-element material of AlGaInP.

16. The light emitting diode structure as claimed in claim 13, wherein said metal substrate is bonded to said multi-layered semiconductor structure by means of a metal bonding technology.

17. The light emitting diode structure as claimed in claim 16, wherein said metal bonding technology is performed through plating a metal bonding layer on said multi-layered semiconductor structure and then bonding said metal substrate to said multi-layered semiconductor structure via said metal bonding layer.

18. The light emitting diode structure as claimed in claim 17, wherein said metal bonding layer is one selected from a group consisting of an AuBe, an AuSn, an AuGe, an AuNi and an AuZn thin films.

19. The light emitting diode structure as claimed in claim 16, wherein said metal bonding technology is performed at a bonding temperature ranged from 300° C. to 900° C.

20. The light emitting diode structure as claimed in claim 16, wherein said metal bonding technology is performed at a bonding temperature ranged from 500 pounds to 5000 pounds.

21. The light emitting diode structure as claimed in claim 13, wherein said first electrode and said second electrode are respectively a P-type electrode and an N-type electrode.

22. The light emitting diode structure as claimed in claim 13, wherein said first electrode and said second electrode are respectively an N-type electrode and a P-type electrode.

23. The light emitting diode structure as claimed in claim 13, wherein said metal substrate is made of a material selected from a group consisting of a Mo, a MoCu alloy, a W, a WCu alloy, a Cr and a CrCu alloy.
